(19) United States
(12) Patent Application Publication
(10) Pub. No.: US 2026/0112419 A1
(43) Pub. Date: Apr. 23, 2026

(54) TRACKING MEMORY CELLS FOR CURRENT LEAKAGE COMPENSATION IN NON-VOLATILE MEMORY ARRAY

(71) Applicant: Silicon Storage Technology, Inc., San Jose, CA (US)

(72) Inventors: Leo XING, Shanghai (CN); Jianhua ZHANG, Shanghai (CN); Brain ZHANG, Shanghai (CN); Yin Shuai WANG, Shanghai (CN); Chuan Hao QU, Shanghai (CN); Adam DOBRI, Westmount QC (CA); Li Fang BAIN, Shanghai (CN); Xiaoyan PI, Shanghai (CN); Xiaozhou QIAN, Shanghai (CN)

(21) Appl. No.: 19/023,251

(22) Filed: Jan. 15, 2025

(30) Foreign Application Priority Data
Oct. 21, 2024 (CN) 202411471092.1

(51) Int. Cl. G11C 16/26; G11C 16/04; G11C 16/34

(52) U.S. Cl. CPC G11C 16/26; G11C 16/0433; G11C 16/3431

(57) ABSTRACT

A method and device for reading memory cells arranged in rows and columns, with bit lines each electrically connected to the memory cells in one of the columns, select gate lines each electrically connected to the memory cells in one of the rows, a column of tracking memory cells, and a tracking bit line electrically connected to the tracking memory cells. The memory cells store user data and the tracking memory cells do not. The method includes performing a primary read operation on one of the memory cells by applying a positive voltage to the memory cell's select gate line resulting in a primary read current on the memory cell's bit line, performing a secondary read operation on the tracking memory cells resulting in a secondary read current on the tracking bit line, detecting the primary read current and compensating the primary read current based on the secondary read current.

### RELATED APPLICATION

This application claims the benefit of Chinese Patent Application No. 202411471092.1, filed on Oct. 21, 2024.

### FIELD OF THE INVENTION

The present disclosure relates to semiconductor devices with arrays of non-volatile memory cells.

### BACKGROUND OF THE INVENTION

Split-gate non-volatile memory semiconductor devices are well known in the art. See for example U.S. Pat. No. 7,868,375, which discloses a four-gate memory cell configuration, and which is incorporated herein by reference for all purposes. Specifically, FIG. 1 of the present disclosure illustrates a pair of split gate non-volatile memory cells 10 each with spaced apart source and drain regions 14, 16 formed in a semiconductor substrate 12 (e.g., silicon). The source region 14 can be referred to as a source line SL (because it commonly is connected to other source regions for other non-volatile memory cells 10 in the same row or column), and the drain region 16 is commonly connected to a bit line. A channel region 18 of the semiconductor substrate 12 extends between the source/drain regions 14/16. A floating gate 20 is disposed over (i.e., vertically over and laterally overlapping) and insulated from (and directly controls the conductivity of) a first portion of the channel region 18 (and partially over, and insulated from, the source region 14). A control gate 22 is disposed over, and insulated from, the floating gate 20. A select gate 24 (also referred to as a word line gate) is disposed over, and insulated from, and directly controls the conductivity of, a second portion of the channel region 18. An erase gate 26 is disposed over and insulated from the source region 14 and is laterally adjacent to the floating gate 20. The erase gate 26 can include a notch that faces an edge of the floating gate 20.

A plurality of such memory cells 10 can be arranged in rows and columns to form a memory cell array, as illustrated in FIG. 2. While FIG. 1 only shows a pair of memory cells 10 (sharing a common source region 14 and erase gate 26), the memory cell pairs can be placed end to end to form a column of memory cells 10 (where the memory cell pairs can share a common drain region 16). While only two such columns are shown in FIG. 2, there can be many such columns. Each column can include a bit line 16a electrically connecting together all the drain regions 16 in the column. Each row of memory cells 10 can include a control gate line 22a electrically connecting together all the control gates 22 in the row of memory cells 10. For example, all the control gates 22 in each row of memory cells 10 can be formed as a continuous line of conductive material, where a portion of the continuous line passing through any given memory cell 10 serves as its control gate 22. Each row of memory cells 10 can include a select gate line 24a (also commonly referred to as a word line) electrically connecting together all the select gates 24 in the row of memory cells 10. For example, all the select gates 24 in each row of memory cells 10 can be formed as a continuous line of conductive material, where a portion of the continuous line passing through any given memory cell 10 serves as its select gate 24. Each row of memory cell pairs can include an erase gate line 26a electrically connecting together all the erase gates 26 in the row of memory cell pairs. For example, all the erase gates 26 in each row of memory cell pairs can be formed as a continuous line of conductive material, where a portion of the continuous line passing through any given memory cell pair serves as its erase gate 26. Finally, each row of memory cell pairs can include a source line 14a electrically connecting together all the source regions 14 in the row of memory cell pairs. For example, all the source regions 14 in each row of memory cell pairs can be formed as a continuous line of conductive diffusion in the semiconductor substrate 12, where a portion of the continuous line passing through any given memory cell pair serves as its source region 14.

Various combinations of voltages are applied to the control gate 22, select gate 24, erase gate 26 and source and drain regions 14/16, to program the split gate non-volatile memory cell 10 (i.e., inject electrons onto the floating gate 20), to erase the split gate non-volatile memory cell 10 (i.e., remove electrons from the floating gate 20), and to read the split gate non-volatile memory cell 10 (i.e., measure or detect the conductivity of the channel region 18, by for example measuring or detecting a read current through the channel region 18, to determine the programming state of the floating gate 20).

Split gate non-volatile memory cell 10 can be operated in a digital manner, where the split gate non-volatile memory cell 10 is set to one of only two possible states: a programmed state and an erased state. The split gate non-volatile memory cell 10 is erased by applying a high positive voltage to the erase gate 26, and optionally a negative voltage to the control gate 22, to induce tunneling of electrons from the floating gate 20 to the erase gate 26 (leaving the floating gate 20 in a more positively charged state—the erased state). Split gate non-volatile memory cell 10 can be programmed by applying positive voltages to the control gate 22, erase gate 26, select gate 24 and source region 14, and a current on drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state).

Split gate non-volatile memory cell 10 can be read by applying positive voltages to the select gate 24 (turning on the portion of channel region 18 under the select gate 24 by making it conductive) and drain region 16 (and optionally on the erase gate 26 and the control gate 22), and sensing current flow through the channel region 18. If the floating gate 20 is positively charged (i.e. split gate non-volatile memory cell 10 is erased), the split gate non-volatile memory cell 10 will turn on because the both portions of the channel region 18 are conductive due to the lack of electrons on the floating gate 20, and electrical current will flow from drain region 16 to source region 14 (i.e. the split gate non-volatile memory cell 10 is sensed to be in its erased “1” state based on sensed current flow). If the floating gate 20 is negatively charged (i.e. split gate non-volatile memory cell 10 is programmed), the portion of channel region 18 under the floating gate is turned off (low conductivity), thereby preventing appreciable current flow (i.e., the split gate non-volatile memory cell 10 is sensed to be in its programmed “0” state based on no, or minimal, current flow). Memory cells 10 are considered non-volatile because they maintain their program state even when power is not applied to the semiconductor device. Memory cells 10 can be referred to as split gate non-volatile memory cells because two different gates (floating gate 20 and select gate 24), respectively, directly control the conductivity of two different portions of the channel region 18.

Split gate non-volatile memory cell 10 can alternately be operated in an analog manner where the program state (i.e. the amount of charge, such as the number of electrons, on the floating gate 20) of the split gate-non-volatile memory cell 10 can be incrementally changed anywhere from a fully erased state (minimum number of electrons on the floating gate 20) to a fully programmed state (maximum number of electrons on the floating gate 20), or just a portion of this range. This means the split gate non-volatile memory cell 10 storage is analog, which allows for very precise and individual tuning of each split gate non-volatile memory cell 10 in an array of split gate non-volatile memory cells 10. Alternatively, the split gate non-volatile memory cell 10 could be operated as an MLC (multilevel cell) where it is configured to be programmed to one of many discrete values (such as 16 or 64 different values).

Split gate non-volatile memory cells with fewer gates are also known. For example, FIG. 3 illustrates known split gate non-volatile memory cells 10 that are the same as that of FIG. 1, except the control gates 22 are omitted. See for example U.S. Pat. No. 7,315,056, which is incorporated herein by reference for all purposes. Voltage coupling to the floating gate 20 provided by the control gate 22 of the split gate non-volatile memory cell 10 of FIG. 1 is provided instead by the erase gate 26 and source region 14 of the split gate non-volatile memory cell 10 in FIG. 3. FIG. 4 illustrates an example layout of an array of the split gate non-volatile memory cells 10 of FIG. 3.

As another example, FIG. 5 illustrates known split gate non-volatile memory cells 10 that are similar to that of FIG. 1, except the control gates 22 and the erase gates 26 are omitted. See for example U.S. Pat. No. 5,029,130, which is incorporated herein by reference for all purposes. The erase voltage for the split gate non-volatile memory cell 10 of FIG. 5 is applied to the select gate 24, which has a first portion laterally adjacent the floating gate 20, and a second portion that extends up and over the floating gate 20. FIG. 6 illustrates an example layout of an array of the split gate non-volatile memory cells 10 of FIG. 5.

As yet another example, FIG. 7 illustrates known split gate non-volatile memory cells 10 that are similar to that of FIG. 5, except a conductive block of material 28 is formed in contact with source region 14, to serve as an extended source line. See for example U.S. Pat. No. 6,855,980, which is incorporated herein by reference for all purposes. An example layout for an array of the split gate non-volatile memory cells 10 of FIG. 7 can be the same as that in FIG. 6.

During a read operation, a current path is created from one of the source lines, through the memory cell being read, and to one of the bit lines. Sense amplifier circuitry is used to detect the current on the bit line during the read operation, where the detected current value is indicative of the program state of the memory cell being read. However, the accuracy of reading a memory cell on a given bit line can be compromised by other memory cells on the same bit line leaking current onto the bit line during the read operation. There is a need to compensate for such leakage current to improve memory cell read accuracy.

### BRIEF SUMMARY OF THE INVENTION

The aforementioned problems and needs are addressed by a semiconductor device comprises a semiconductor substrate, a first array of memory cells arranged in rows and columns on the semiconductor substrate, bit lines each electrically connected to the memory cells in one of the columns of the memory cells, select gate lines each electrically connected to the memory cells in one of the rows of the memory cells, tracking memory cells arranged in a column, a tracking bit line electrically connected to the tracking memory cells, control circuitry and sense amplifier circuitry. The control circuitry to store user data in the memory cells and not in the tracking memory cells, perform a primary read operation on a first one of the memory cells that is electrically connected to one of the bit lines and to one of the select gate lines, wherein the primary read operation includes application of a positive voltage to the one select gate line and results in a primary read current on the one bit line, and perform a secondary read operation on the column of tracking memory cells that results in a secondary read current on the tracking bit line. The sense amplifier circuitry to detect the primary read current, and compensate the primary read current based on the secondary read current.

A method of reading a memory cell in semiconductor device that comprises a semiconductor substrate, a first array of memory cells arranged in rows and columns on the semiconductor substrate, bit lines each electrically connected to the memory cells in one of the columns of the memory cells, select gate lines each electrically connected to the memory cells in one of the rows of the memory cells, tracking memory cells arranged in a column, and a tracking bit line electrically connected to the tracking memory cells, wherein the memory cells are configured to store user data and the tracking memory cells are not configured to store user data. The method comprising performing a primary read operation on a first one of the memory cells that is electrically connected to one of the bit lines and to one of the select gate lines, wherein the primary read operation includes applying a positive voltage to the one select gate line and results in a primary read current on the one bit line, performing a secondary read operation on the column of tracking memory cells that results in a secondary read current on the tracking bit line, detecting the primary read current, and compensating the primary read current based on the secondary read current.

Other objects and features of the present disclosure will become apparent by a review of the specification, claims and appended figures.

### BRIEF DESCRIPTION OF THE DRAWINGS

FIG. 1 is a cross sectional view of a conventional pair of memory cells.

FIG. 2 is a schematic and layout diagram of a conventional memory cell array of the memory cells of FIG. 1.

FIG. 3 is a side cross sectional view of a conventional pair of memory cells.

FIG. 4 is a schematic and layout diagram of a conventional memory cell array of the memory cells of FIG. 3.

FIG. 5 is a side cross sectional view of a conventional pair of memory cells.

FIG. 6 is a schematic and layout diagram of a conventional memory cell array of the memory cells of FIG. 5.

FIG. 7 is a side cross sectional view of a conventional pair of memory cells.

FIG. 8 is a diagram illustrating components of a semiconductor device.

FIG. 9 is a schematic and layout diagram of a conventional array of a semiconductor device.

FIG. 10 is a schematic and layout diagram of a conventional array of a semiconductor device.

FIG. 11 is a schematic and layout diagram of an array of a semiconductor device according to a first example.

FIG. 12 is a schematic and layout diagram of an array of a semiconductor device according to a second example.

FIG. 13 is a schematic and layout diagram of an array of a semiconductor device according to a third example.

FIG. 14 is a schematic and layout diagram of an array of a semiconductor device according to a fourth example.

FIG. 15 is a schematic and layout diagram of an array of a semiconductor device according to a fifth example.

FIG. 16 is a schematic and layout diagram of an array of a semiconductor device according to a sixth example.

### DETAILED DESCRIPTION OF THE INVENTION

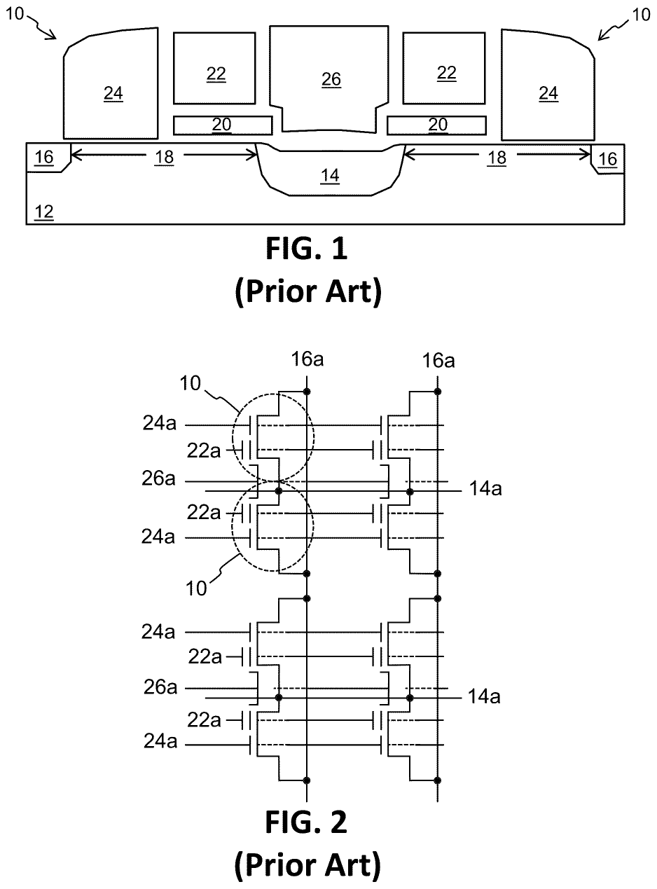

The present examples illustrate memory cell array configurations that improve read operation accuracy, and can be better understood from the architecture of an example semiconductor device as illustrated in FIG. 8. The semiconductor device includes an array 30 of the split gate memory cells 10, which can be segregated into two separate planes (Plane A 32a and Plane B 32b). The split gate memory cells 10 can be of the type shown in FIG. 1, 3, 5 or 7, arranged in rows and columns in the semiconductor substrate 12 as illustrated in FIG. 2, 4 or 6, and thus formed on a single semiconductor chip. Adjacent to the array 30 of split gate memory cells 10 are an address decoder 34 (e.g., XDEC), source line drivers 36 (e.g., SLDRV), a column decoder 38 (e.g., YMUX), a high voltage row decoder 40 (e.g., HVDEC), a bit line controller 42 (e.g., BLINHCTL), and a charge pump 44 (e.g., CHRGPMP), which are used to decode addresses and apply the various voltages to the various gates and regions of the split gate memory cells 10 during read, program, and erase operations for selected split gate memory cells 10 of the array 30, under the control of the control circuitry 46. Column decoder 38 includes sense amplifier circuitry for detecting the currents on the bit lines during a read operation. Control circuitry 46 controls the various device elements to implement each operation (program, erase, read) on selected split gate memory cells 10 of the array 30 as described herein. Control circuitry 46 operates the semiconductor device to program, erase and read the selected split gate memory cells 10 of the array 30. As part of these operations, the control circuitry 46 can be provided with access to incoming data which is user data to be programmed to the selected split gate memory cells 10 of the array 30, along with program, erase and read commands provided on the same or different lines. Data read from the array 30 (i.e., from selected split gate memory cells 10 of the array 30) is provided as outgoing data. Control circuitry 46 is configured to implement the primary read operations and secondary read operations described in more detail below.

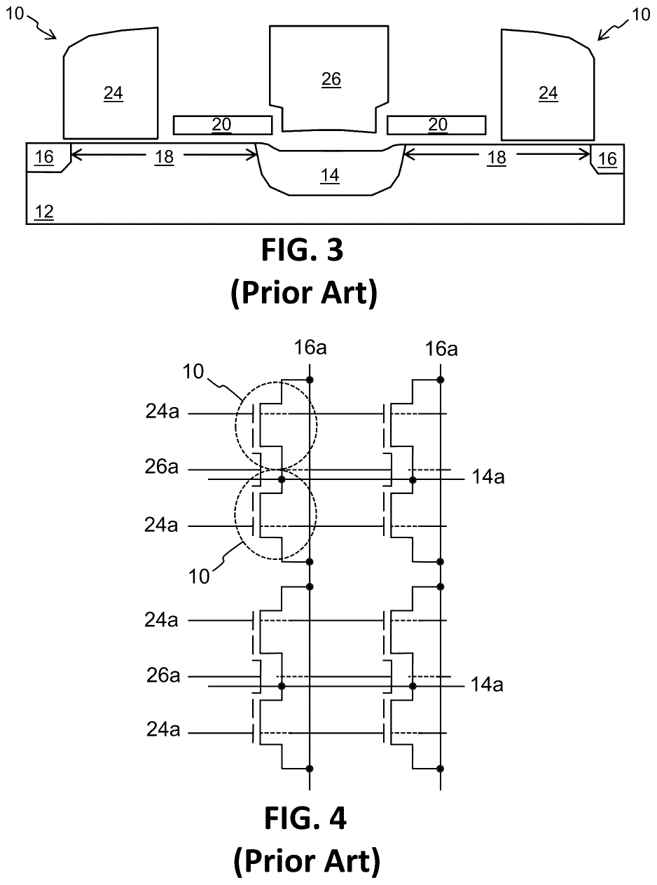

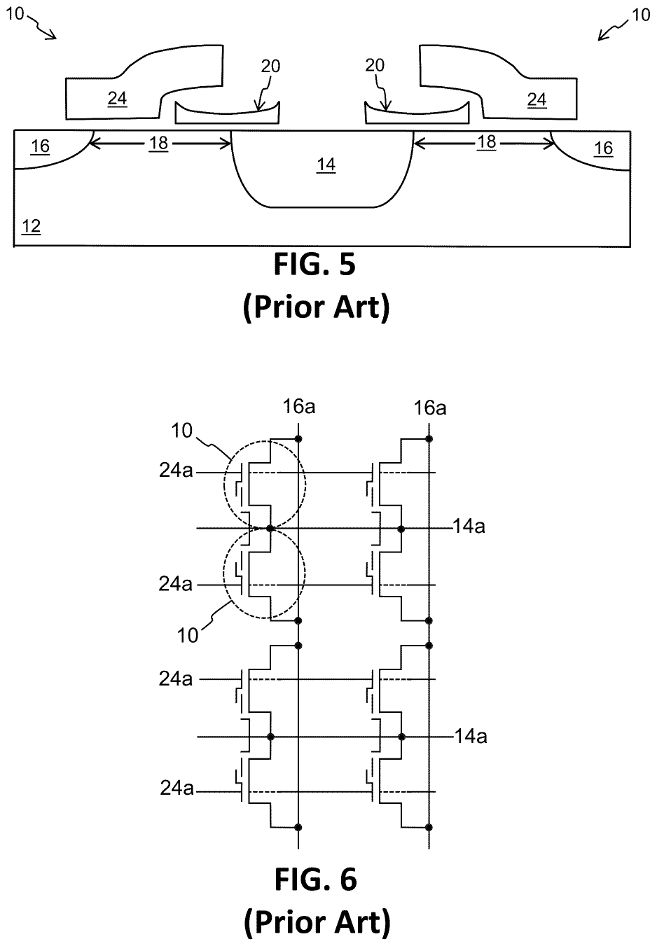

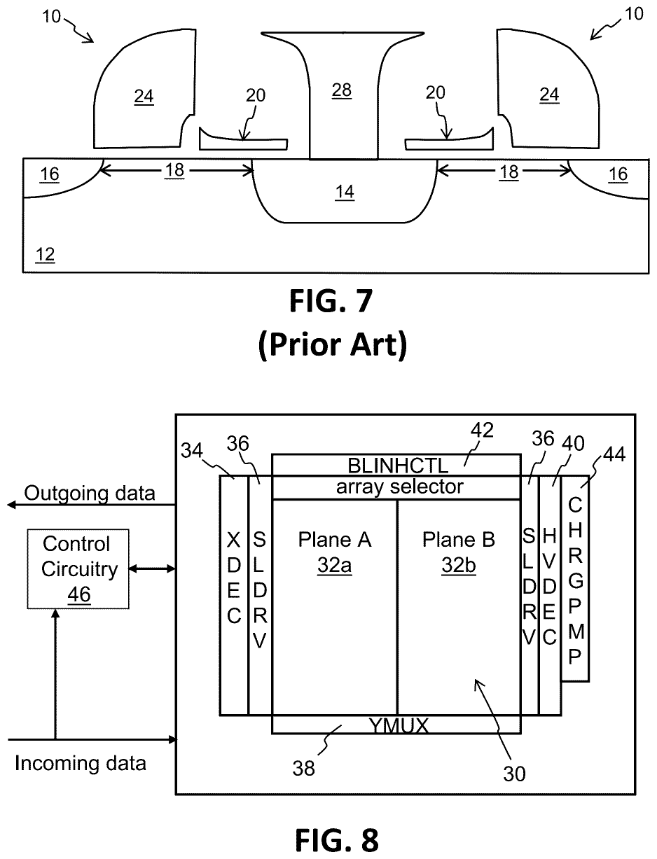

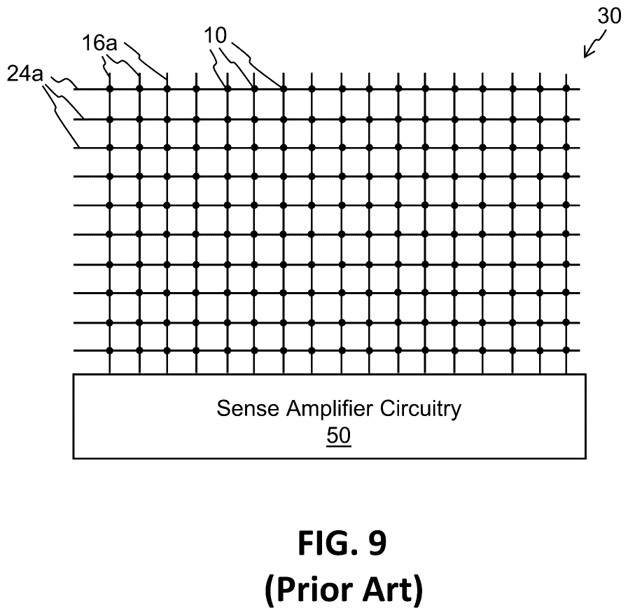

FIG. 9 is a simplified representation of array 30, showing bit lines 16a and select gate lines 24a, and memory cells 10 at each intersection of bit lines 16a and select gate lines 24a. The memory cells 10 can be of the type shown in FIG. 1, 3, 5 or 7, arranged as illustrated in FIG. 2, 4 or 6. Any additional lines that may be present (e.g., control gate lines 22a, erase gate lines 26a) depending upon which memory cell configuration is used (i.e., four gate memory cell of FIG. 1, three gate memory cell of FIG. 3, or two gate memory cell of FIG. 5 or 7), as well as source lines 14a, have been omitted from FIG. 9 for simplicity, but it should be noted that bit lines 16a and select gate lines 24a are included in arrays of the memory cells of FIG. 1, 3, 5 or 7. Sense amplifier circuitry 50 is connected to and includes circuitry for detecting the electrical current on the bit lines 16a (e.g., during read operations, referred to herein as “read current”). During a read operation to read a selected memory cell 10 on one of the bit lines 16a, a positive voltage is applied to the select gate line 24a for the selected memory cell 10 (along with the other read voltages discussed above), and the read current on the bit line 16a for the selected memory cell 10 is detected by sense amplifier circuitry 50. Zero or ground voltage is applied to all the other select gate lines 24a for all the other memory cells 10 on the same bit line 16a (the non-selected memory cells), effectively turning those memory cells off, so theoretically the only read current on the bit line 16a containing the selected memory cell should be the current flowing through the selected memory cell 10 (which is indicative of the program state of the selected memory cell). In reality, however, a non-negligible amount of leakage current can flow through some or all of the non-selected memory cells on the same bit line 16a as the selected memory cell 10, collectively contributing to the read current on the bit line 16a. The cumulative leakage current from all the non-selected memory cells 10 on the same bit line 16a as the selected memory cell 10 can be difficult to approximate with accuracy because the cumulative leakage current can vary based upon the operating temperature of the semiconductor device, the program states of the non-selected memory cells on the same bit line 16a as the selected memory cell 10 being read, the location of the bit line 16a within the semiconductor chip, and from manufacturing and material variations between different semiconductor chips. However, the cumulative leakage current will make the read current on the bit line 16a artificially high, thus decreasing the accuracy of the read operation.

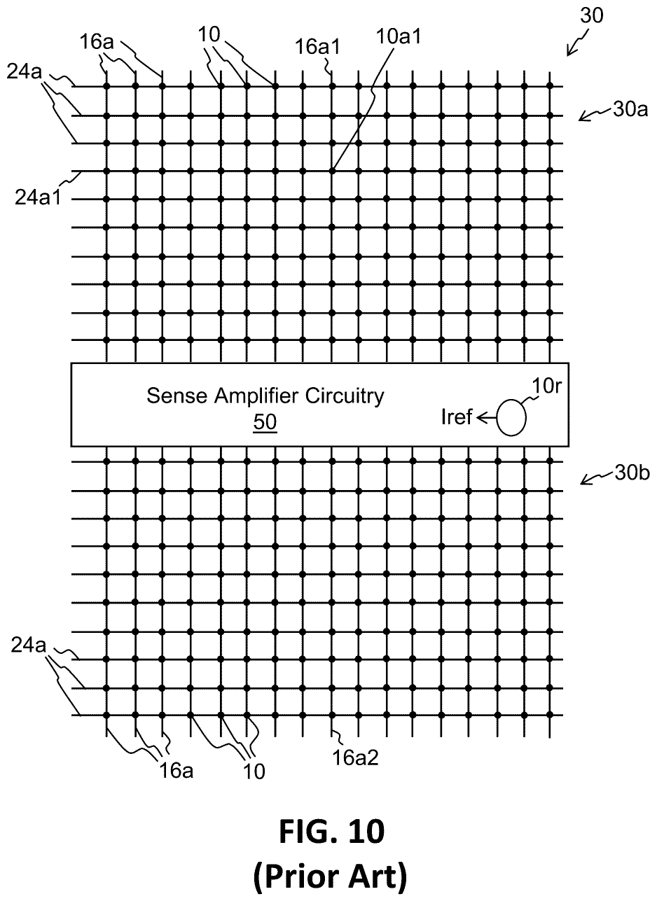

FIG. 10 illustrates a conventional configuration and method to compensate for RC delay of the read current on one bit line using read current on another bit line. The array 30 can include two sub-arrays 30a and 30b (also referred to as first array 30a and second array 30b), both connected to the sense amplifier circuitry 50 and both configured to store user data in their memory cells 10. When performing a primary read operation for a selected memory cell 10a1 in first array 30a (to determine its program state by measuring the read current through the selected memory cell 10a1), a secondary read operation is simultaneously performed in second array 30b on a bit line for which all the memory cells 10 connected thereto are turned off. Specifically, for performing a primary read operation on selected memory cell 10a1 (which is connected to bit line 16a1 and select gate line 24a1 in first array 30a), a positive voltage is applied to the select gate line 24a1 (along with the other read voltages discussed above), and zero or ground voltage is applied to all the other select gate lines 24a of first array 30a (effectively turning off the non-selected memory cells 10 connected to bit line 16a1). The primary read current Iprc (from the primary read operation) on bit line 16a1 of first array 30a will be the electrical current through selected memory cell 10a1 (the amplitude of which will be dictated by its program state), and any leakage current from the other memory cells 10 connected to bit line 16a1. For the secondary read operation of second array 30b, zero or ground voltage is applied to all of the select gate lines 24a of second array 30b, effectively turning off all the memory cells in second array 30b. The secondary read current Isrc (from the secondary read operation) on bit line 16a2 of second array 30b will be any leakage current from the memory cells 10 connected to bit line 16a2.

Conventionally, the secondary read current Isrc has been used to compensate for RC delay of the primary read current Iprc. For example, the sense amplifier circuitry 50 can include an optional reference memory cell 10r that generates a reference current Iref which is compared against the detected primary read current Iprc as part of the primary read operation to determine the program state of the selected memory cell being read. To compensate for RC delay, it is known to add the secondary read current Isrc to the reference current Iref.

While the secondary read current Isrc on bit line 16a2 results from leakage current from the memory cells 10 connected to bit line 16a2, it does not provide an accurate measure or indicator of the leakage current on bit line 16a1, because the memory cells connected to bit line 16a2 of second array 30b are used to store data, and the programming states of those memory cells can affect the leakage current through the memory cells during the secondary read operation of second array 30b. Therefore, because the leakage current during a secondary read operation on bit line 16a2 will vary depending on the data programmed to the memory cells on bit line 16a2, and will change when the programmed data is changed, the leakage current from a secondary read operation on bit line 16a2 is not a good approximation of the leakage current from a primary read operation on bit line 16a1.

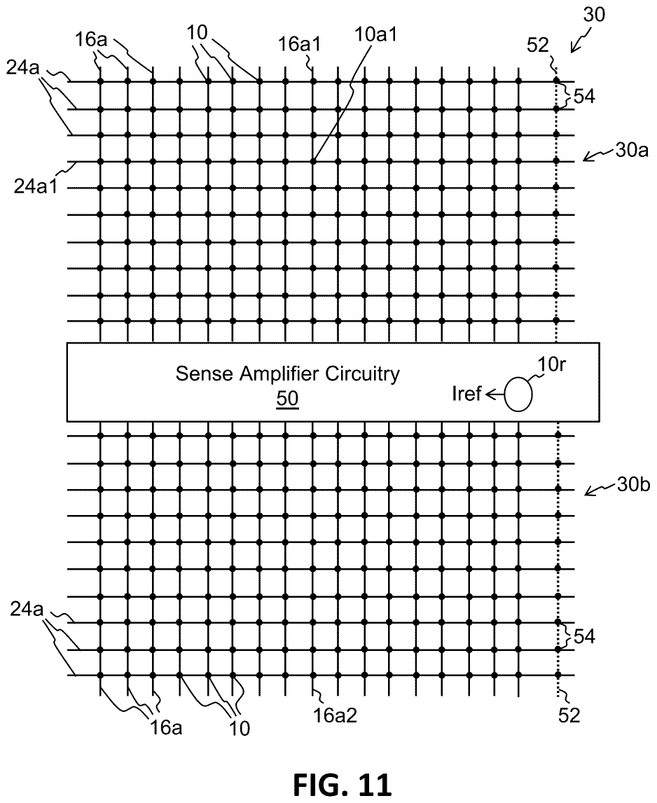

FIG. 11 illustrates a first example of a configuration and method to compensate for the leakage current. The array 30 is the same as that in FIG. 10, except that first array 30a and second array 30b each include one or more columns of tracking memory cells 54 connected to a tracking bit line 52. The tracking memory cells 54 have the same configuration as memory cells 10, and are electrically connected to the other lines of the first and second arrays 30a and 30b (other than bit lines 16a) in the same manner as are memory cells 10. Specifically, tracking memory cells 54 are electrically connected to source lines 14a, select gate lines 24a, control gate lines 22a (if included), and erase gate lines 26a (if included). However, the tracking memory cells 54 are not used to store data. The tracking memory cells 54 can remain in a fixed program state over time (e.g., erased state, programmed state, or a programming state there between). When performing a primary read operation for a selected memory cell 10a1 in first array 30a, a secondary read operation is simultaneously performed on tracking memory cells 54 connected to tracking bit line 52 in second array 30b. The secondary read current Isrc on tracking bit line 52 in second array 30b will better approximate the leakage current portion of primary read current Iprc in first array 30a in comparison to using one of the bit lines 16a of second array 30b because the program states of the tracking memory cells 54 connected to tracking bit line 52 do not vary over time (because tracking memory cells 54 are not used to store user data). It should be noted that when a primary read operation for a selected memory cell in second array 30b is performed, the secondary read operation described above can be simultaneously performed on the tracking memory cells 54 connected to tracking bit line 52 of first array 30a.

The primary read current Iprc compensation can implemented by the sense amplifier circuitry 50. For example, the secondary read current Isrc can be subtracted from the primary read current Iprc, before the sense amplifier circuitry 50 detects the primary read current Iprc. As another example, the sense amplifier circuitry 50 can detect and determine values for the primary read current Iprc (e.g., convert the primary read current to a primary read value) and for the secondary read current Isrc (e.g., convert the secondary read current to a secondary read value), whereby the secondary read value is subtracted from the primary read value. As yet another example, the sense amplifier circuitry 50 can include an optional reference memory cell 10r that generates a reference current Iref which is compared against the detected primary read current Iprc as part of the primary read operation to determine the program state of the selected memory cell being read. The reference memory cell 10r can have the same configuration as memory cells 10. When a reference memory cell 10r is used, the primary read current Iprc compensation can include adding the secondary read current Isrc from the second read operation to the reference current Iref, where the reference current Iref that includes the added secondary read current Isrc is compared to the primary read current Iprc.

While the tracking memory cells 54 in the example of FIG. 11 can be connected to all the various lines of the first and second arrays 30a, 30b (except bit lines 16a), they need not be. For example, one or more of the lines extending in the row direction and connected to the memory cells 10, such as source lines 14a, select gate lines 24a, control gate lines 22a (if included) and erase gate lines 26a (if included), can be electrically isolated from the tracking memory cells 54. A separate set of such lines can optionally be connected to the tracking memory cells 54 to optionally program the tracking memory cells 54 or to have the tracking memory cells 54 provide leakage current that better matches the leakage current of the memory cells 10.

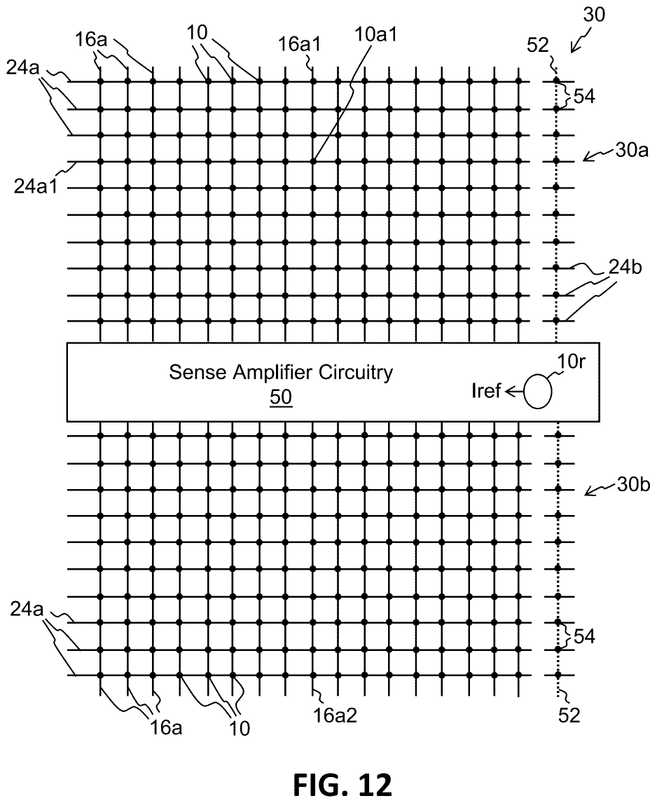

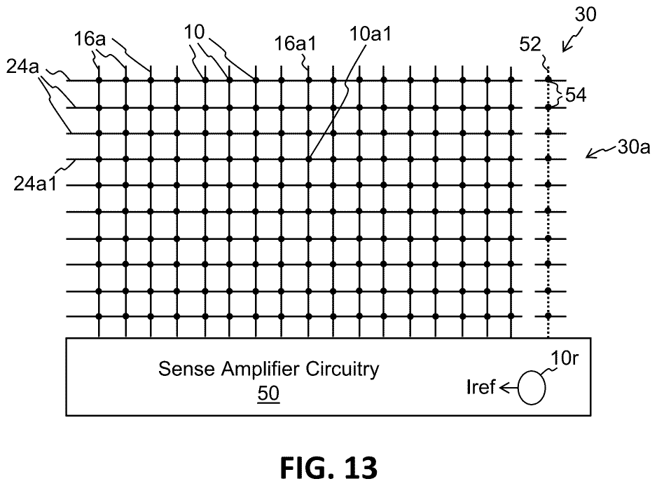

As a second example, the select gate lines 24a electrically connected to the memory cells 10 can be electrically isolated from select gate lines 24b (which are optional) that are electrically connected to the tracking memory cells 54, as illustrated in FIG. 12. One advantage of this configuration is that tracking memory cells 54 in the same array as the memory cell being read can be used for read current compensation because the tracking memory cells 54 are electrically isolated from the select gate lines 24a. As shown in FIG. 12, the primary read operation and the secondary read operation can be performed simultaneously to first array 30a, where the primary read operation is performed on selected memory cell 10a1 of first array 30a, and the secondary read operation is performed on the tracking memory cells 54 in first array 30a. The integrity of the secondary read current Isrc on the tracking bit line 52 is maintained because any voltages applied to the select gate lines 24a of first array 30a do not reach any of the select gate lines 24b connected to the tracking memory cells 54 of first array 30a. Conversely, the primary read operation and secondary read operation can be performed simultaneously to the second array 30b. Another advantage of this configuration is that first array 30a can be operated independently of second array 30b (i.e., simultaneous primary and secondary read operations can performed on first array 30a while simultaneous primary and secondary read operations are performed on second array 30b). Further, second array 30b can be omitted or isolated from first array 30a, where sense amplifier circuitry 50 can be operated without reliance on any other arrays, as shown as a third example in FIG. 13. Yet one more advantage of this configuration is that it allows for an optional negative voltage to be applied to the select gates 24 of the tracking memory cells 52 as part of the secondary read operation, which can result in the secondary read current Isrc on tracking bit line 52 better approximating the leakage current portion of primary read current Iprc.

Another advantage of the examples of FIGS. 12 and 13 is that for memory cell configurations where the select gate is used to erase the memory cells (e.g., the memory cells and array configurations of FIGS. 5-7), the tracking memory cells 54 are not erased when memory cells 10 are erased. Therefore, the tracking memory cells 54 can be programmed and left in program states different from the erased state that may better reflect the leakage current of the primary read operation (i.e., the tracking memory cells 54 can be programmed to a partially or fully programmed state to reduce the secondary read current Isrc on the tracking bit line 52). This same advantage can be achieved for memory cells and array configuration of FIGS. 1-4, by having the erase gate lines 26a electrically connected to the memory cells 10 be electrically isolated from the erase gates 26 of the tracking memory cells 54 (so that erasing memory cells 10 does not result in erasing tracking memory cells 54). Further, if the source lines 14a electrically connected to the memory cells 10 are electrically isolated from the source regions 14 of the tracking memory cells 54, then a smaller bias voltage can be used on the source regions 14 of the tracking memory cells 54 for the secondary read operation (to reduce secondary read current Isrc) relative to the bias voltage used on the source regions 14 of the memory cells 10 for the primary read operation.

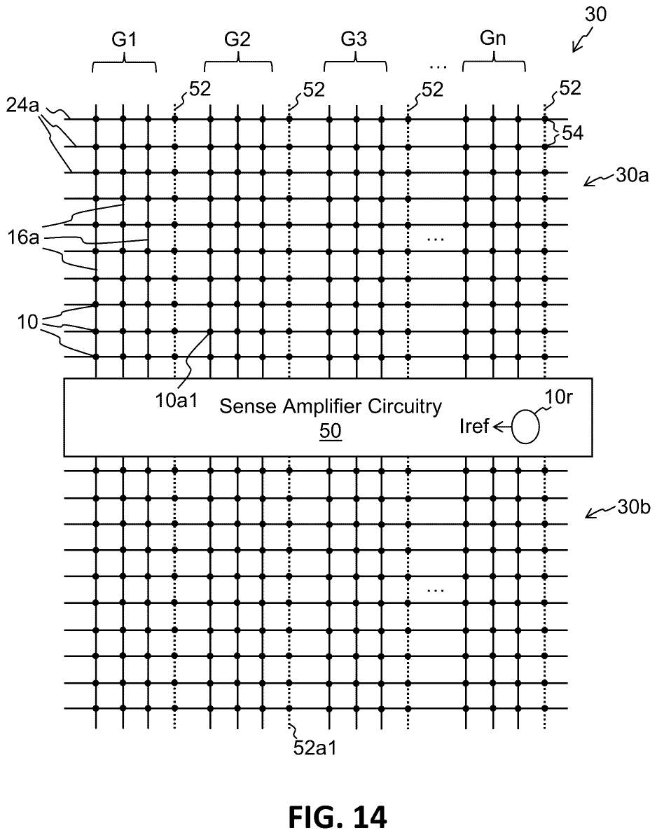

FIG. 14 illustrates a fourth example, where for each of first array 30a and second array 30b, the columns of memory cells 10 used to store user data and the bit lines 16a connected thereto are arranged in groups G1 to Gn, where a column of tracking memory cells 54 connected to a tracking bit line 52 is disposed adjacent to each group G. By providing multiple columns of tracking memory cells 54 and tracking bit lines 52 intermittently throughout the first array 30a and second array 30b, the secondary read operation can be performed on a column of tracking memory cells 54 and tracking bit line 52 that is spatially closer to the selected memory cell 10a1 being read by the primary read operation. In the example of FIG. 14, when conducting the primary read operation on selected memory cell 10a1 in group G2 of first array 30a, the secondary read operation is conducted on tracking memory cells 54 electrically connected to tracking bit line 52a1 of second array 30b which is adjacent to group G2. The closer proximity of the tracking bit line 52a1 to the selected memory cell 10a1 can provide better read operation compensation for memory arrays having large numbers of memory cell columns as well as memory arrays where current leakage varies from one area of array 30 to another area of array 30.

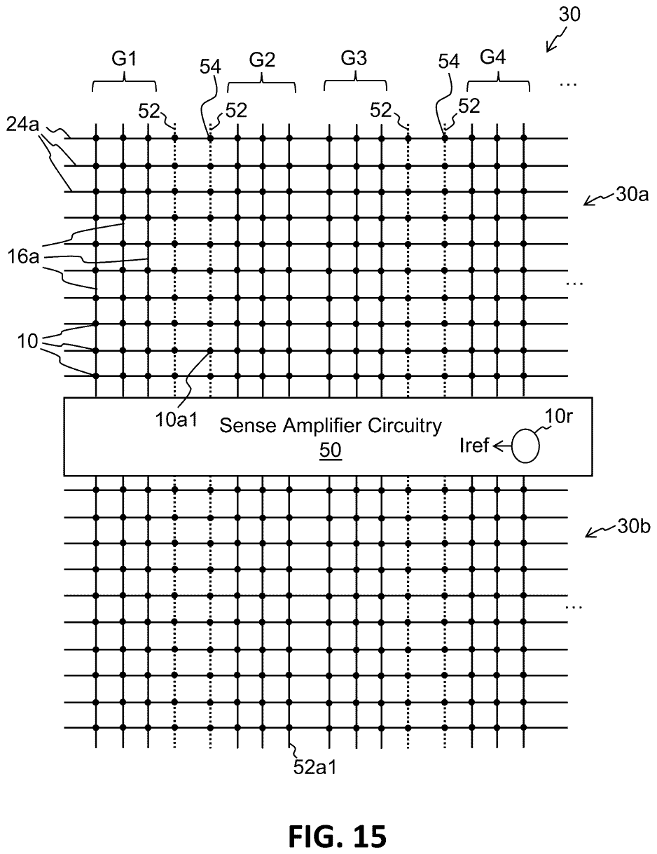

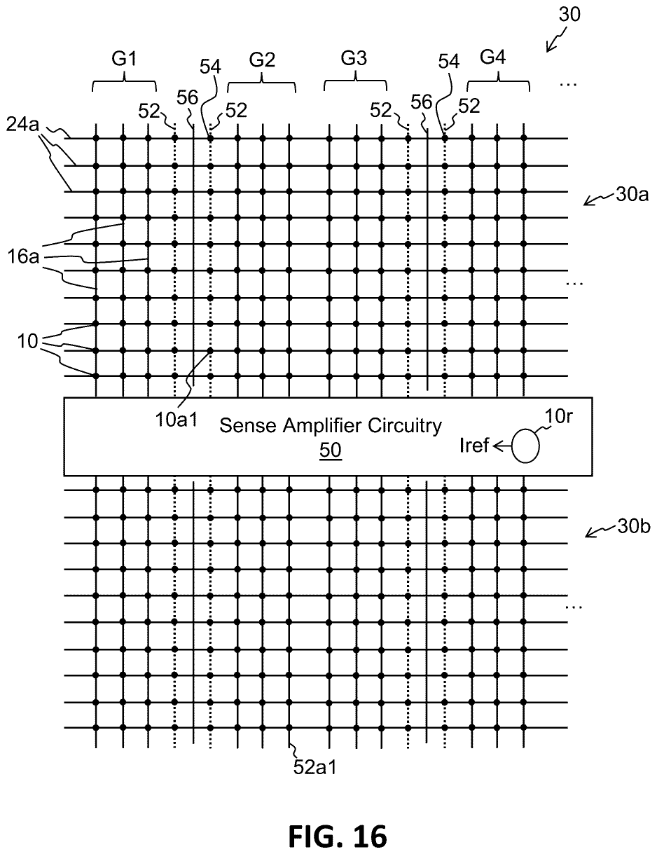

FIG. 15 illustrates a fifth example, which is similar to the fourth example of FIG. 14, but the pair of the columns of tracking memory cells 54 and the associated tracking bit lines 52 for two groups G of columns of memory cells 10 are adjacent to each other (e.g., a pair of the columns of tracking memory cells 54 and their associated tracking bit lines 52 are disposed between groups G1 and G2 of memory cells 10). This configuration has the advantage that the tracking bit lines 52 are better capacitance matched to bit lines 16a.

FIG. 16 illustrates a sixth example, which is similar to the fifth example of FIG. 15, but a tracking source line 56 is added for each adjacent pair of tracking bit lines 52, where each tracking source line 56 is electrically connected to the source regions 14 of the tracking memory cells 54 connected to the pair of tracking bit lines 52. The tracking source lines 56 are electrically isolated from the source lines 14a for memory cells 10. For example, for each row of memory cells 10, the source line 14a can include diffusion connecting the source regions 14 within a single group G, and a strap line for connecting together the diffusions of the various groups G. With this configuration, the tracking source line 56 can be operated separately from the source lines 14a, so that a smaller bias voltage can be applied to source regions 14 of the tracking memory cells 54 for the secondary read operation (to reduce secondary read current Isrc) relative to the bias voltage applied to the source regions 14 of the memory cells 10 for the primary read operation.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper operation of the semiconductor device described herein. Finally, the claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry. Finally, it should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between).

What is claimed is:

1. A semiconductor device comprising:
a semiconductor substrate;
a first array of memory cells arranged in rows and columns on the semiconductor substrate;
bit lines each electrically connected to the memory cells in one of the columns of the memory cells;
select gate lines each electrically connected to the memory cells in one of the rows of the memory cells;
tracking memory cells arranged in a column;
a tracking bit line electrically connected to the tracking memory cells;
control circuitry to:
store user data in the memory cells and not in the tracking memory cells,
perform a primary read operation on a first one of the memory cells that is electrically connected to one of the bit lines and to one of the select gate lines, wherein the primary read operation includes application of a positive voltage to the one select gate line and results in a primary read current on the one bit line, and
perform a secondary read operation on the column of tracking memory cells that results in a secondary read current on the tracking bit line; and
sense amplifier circuitry to:
detect the primary read current, and
compensate the primary read current based on the secondary read current.

2. The semiconductor device of claim 1, wherein the control circuitry is configured to perform the primary read operation and the secondary read operation simultaneously.

3. The semiconductor device of claim 1, wherein the compensate the primary read current based on the secondary read current comprises subtract the secondary read current from the primary read current.

4. The semiconductor device of claim 1, wherein the compensate the primary read current based on the secondary read current comprises convert the primary read current to a primary read value, convert the secondary read current to a secondary read value, and subtract the secondary read value from the primary read value.

5. The semiconductor device of claim 1, wherein the compensate the primary read current based on the secondary read current comprises generate a reference current from a reference memory cell, add the secondary read current to the reference current, and compare the reference current with the added secondary read current to the primary read current.

6. The semiconductor device of claim 1, wherein each of the memory cells and the tracking memory cells comprises:
a source region and a drain region formed in the semiconductor substrate, with a channel region of the semiconductor substrate extending between the source region and the drain region;
a floating gate disposed over a first portion of the channel region for controlling a conductivity of the first portion of the channel region; and
a select gate disposed over a second portion of the channel region for controlling a conductivity of the second portion of the channel region;
wherein each of the bit lines is electrically connected to the drain regions of the memory cells in one of the columns of the memory cells;
wherein each of select gate lines is electrically connected to the select gates of the memory cells in one of the rows of the memory cells;
wherein the tracking bit line is electrically connected to the drain regions of the tracking memory cells.

7. The semiconductor device of claim 6, comprising:
source lines each electrically connected to the source regions of the memory cells in one of the rows of the memory cells, and each electrically isolated from the source regions of the tracking memory cells.

8. The semiconductor device of claim 7, wherein:
the primary read operation includes application of a first positive voltage to one of the source lines that is electrically connected to the first one of the memory cells;
the secondary read operation includes application of a second positive voltage to the source regions of the tracking memory cells; and
the second positive voltage is less than the first positive voltage.

9. The semiconductor device of claim 6, wherein each of the memory cells and the tracking memory cells comprises an erase gate disposed over the source region, and wherein the semiconductor device further comprises erase gate lines each electrically connected to the erase gates of the memory cells in one of the rows of the memory cells.

10. The semiconductor device of claim 9, wherein the erase gate lines are electrically isolated from the erase gates of the tracking memory cells.

11. The semiconductor device of claim 9, wherein each of the memory cells and the tracking memory cells comprises a control gate disposed over the floating gate, and wherein the semiconductor device further comprises control gate lines each electrically connected to the control gates of the memory cells in one of the rows of the memory cells.

12. The semiconductor device of claim 11, wherein the control gate lines are electrically isolated from the control gates of the tracking memory cells.

13. The semiconductor device of claim 1, comprising:
a second array of second memory cells arranged in rows and columns on the semiconductor substrate;
second bit lines each electrically connected to the second memory cells in one of the columns of the second memory cells; and
second select gate lines each electrically connected to the second memory cells in one of the rows of the second memory cells and to one of the tracking memory cells;
wherein the column of tracking memory cells is disposed adjacent to one of the columns of the second memory cells.

14. The semiconductor device of claim 13, comprising:
second tracking memory cells arranged in a column;
a second tracking bit line electrically connected to the second tracking memory cells;
the column of tracking memory cells is disposed adjacent to a first group of the columns of the second memory cells; and
the column of second tracking memory cells is disposed adjacent to a second group of the columns of the second memory cells different from the first group of the columns of the second memory cells.

15. The semiconductor device of claim 14, wherein:
the control circuitry is configured to:
store user data in the second memory cells and not in the second tracking memory cells,
perform a second primary read operation on a second one of the memory cells electrically connected to a second one of the bit lines and a second one of the select gate lines, wherein the second primary read operation includes application of a positive voltage to the second one of the select gate lines and results in a second primary read current on the second one of the bit lines, and
perform a second secondary read operation on the column of second tracking memory cells that results in a second secondary read current on the second tracking bit line; and
the sense amplifier circuitry is configured to:
detect the second primary read current, and
compensate the second primary read current based on the second secondary read current.

16. The semiconductor device of claim 15, wherein the column of tracking memory cells and the column of second tracking memory cells are disposed between the first group of the columns of the second memory cells and the second group of the columns of the second memory cells.

17. The semiconductor device of claim 16, comprising:
source lines each electrically connected to the memory cells in one of the rows of the memory cells;
second source lines each electrically connected to second memory cells in one of the rows of the second memory cells; and
a tracking source line electrically connected to the tracking memory cells and the second tracking memory cells, and electrically isolated from the source lines and the second source lines.

18. The semiconductor device of claim 6, wherein:
the tracking memory cells are disposed adjacent one of the columns of the memory cells; and
the select gate lines are electrically isolated from the tracking memory cells.

19. The semiconductor device of claim 18, wherein the secondary read operation includes application of a negative voltage to the select gates of the tracking memory cells.

20. A method of reading a memory cell in semiconductor device that comprises a semiconductor substrate, a first array of memory cells arranged in rows and columns on the semiconductor substrate, bit lines each electrically connected to the memory cells in one of the columns of the memory cells, select gate lines each electrically connected to the memory cells in one of the rows of the memory cells, tracking memory cells arranged in a column, and a tracking bit line electrically connected to the tracking memory cells, wherein the memory cells are configured to store user data and the tracking memory cells are not configured to store user data, the method comprising:
performing a primary read operation on a first one of the memory cells that is electrically connected to one of the bit lines and to one of the select gate lines, wherein the primary read operation includes applying a positive voltage to the one select gate line and results in a primary read current on the one bit line;
performing a secondary read operation on the column of tracking memory cells that results in a secondary read current on the tracking bit line;
detecting the primary read current; and
compensating the primary read current based on the secondary read current.

21. The method of claim 20, wherein the primary read operation and the secondary read operation are performed simultaneously.

22. The method of claim 20, wherein the compensating the primary read current based on the secondary read current comprises subtracting the secondary read current from the primary read current.

23. The method of claim 20, wherein the compensating the primary read current based on the secondary read current comprises:
converting the primary read current to a primary read value;
converting the secondary read current to a secondary read value; and
subtracting the secondary read value from the primary read value.

24. The method of claim 20, wherein the compensating the primary read current based on the secondary read current comprises:
generating a reference current from a reference memory cell;
adding the secondary read current to the reference current; and
comparing the reference current with the added secondary read current to the primary read current.

25. The method of claim 20, wherein each of the memory cells and the tracking memory cells comprises:
a source region and a drain region formed in the semiconductor substrate, with a channel region of the semiconductor substrate extending between the source region and the drain region;
a floating gate disposed over a first portion of the channel region for controlling a conductivity of the first portion of the channel region; and
a select gate disposed over a second portion of the channel region for controlling a conductivity of the second portion of the channel region;
wherein each of the bit lines is electrically connected to the drain regions of the memory cells in one of the columns of the memory cells;
wherein each of select gate lines is electrically connected to the select gates of the memory cells in one of the rows of the memory cells;
wherein the tracking bit line is electrically connected to the drain regions of the tracking memory cells.

26. The method of claim 25, wherein the semiconductor device comprises:
source lines each electrically connected to the source regions of the memory cells in one of the rows of the memory cells, and each electrically isolated from the source regions of the tracking memory cells.

27. The method of claim 26, wherein:
the performing the primary read operation includes applying a first positive voltage to one of the source lines that is electrically connected to the first one of the memory cells;
the performing the secondary read operation includes applying a second positive voltage to the source regions of the tracking memory cells; and
the second positive voltage is less than the first positive voltage.

28. The method of claim 26, wherein each of the memory cells and the tracking memory cells comprises an erase gate disposed over the source region, and wherein the semiconductor device further comprises erase gate lines each electrically connected to the erase gates of the memory cells in one of the rows of the memory cells.

29. The method of claim 28, wherein the erase gate lines are electrically isolated from the erase gates of the tracking memory cells.

30. The method of claim 28, wherein each of the memory cells and the tracking memory cells comprises a control gate disposed over the floating gate, and wherein the semiconductor device further comprises control gate lines each electrically connected to the control gates of the memory cells in one of the rows of the memory cells.

31. The method of claim 30, wherein the control gate lines are electrically isolated from the control gates of the tracking memory cells.

32. The method of claim 20, wherein the semiconductor device comprises:
a second array of second memory cells arranged in rows and columns on the semiconductor substrate;
second bit lines each electrically connected to the second memory cells in one of the columns of the second memory cells; and
second select gate lines each electrically connected to the second memory cells in one of the rows of the second memory cells and to one of the tracking memory cells;
wherein the column of tracking memory cells is disposed adjacent to one of the columns of the second memory cells.

33. The method of claim 32, wherein the semiconductor device comprises:
second tracking memory cells arranged in a column;
a second tracking bit line electrically connected to the second tracking memory cells;
the column of tracking memory cells is disposed adjacent to a first group of the columns of the second memory cells; and
the column of second tracking memory cells is disposed adjacent to a second group of the columns of the second memory cells different from the first group of the columns of the second memory cells.

34. The method of claim 33, wherein the second memory cells are configured to store user data and the second tracking memory cells are not configured to store user data, the method comprises:
performing a second primary read operation on a second one of the memory cells electrically connected to a second one of the bit lines and a second one of the select gate lines, wherein the second primary read operation includes applying a positive voltage to the second one of the select gate lines and results in a second primary read current on the second one of the bit lines;
performing a second secondary read operation on the column of second tracking memory cells that results in a second secondary read current on the second tracking bit line;
detecting the second primary read current; and
compensating the second primary read current based on the second secondary read current.

35. The method of claim 34, wherein the column of tracking memory cells and the column of second tracking memory cells are disposed between the first group of the columns of the second memory cells and the second group of the columns of the second memory cells.

36. The method of claim 35, comprising:
source lines each electrically connected to the memory cells in one of the rows of the memory cells;
second source lines each electrically connected to second memory cells in one of the rows of the second memory cells; and
a tracking source line electrically connected to the tracking memory cells and the second tracking memory cells, and electrically isolated from the source lines and the second source lines.

37. The method of claim 25, wherein:
the tracking memory cells are disposed adjacent one of the columns of the memory cells; and
the select gate lines are electrically isolated from the tracking memory cells.

38. The method of claim 37, wherein the performing the secondary read operation includes applying a negative voltage to the select gates of the tracking memory cells.
